(19) United States
(12) Patent Application Publication
(10) Pub. No.: US 2019/0116661 A1
(43) Pub. Date: Apr. 18, 2019

(54) WIRING BOARD AND MANUFACTURING METHOD FOR WIRING BOARD

(71) Applicant: FUJITSU LIMITED, Kawasaki-shi (JP)

(72) Inventor: TAKASHI FUKUDA, Machida (JP)

(73) Assignee: FUJITSU LIMITED, Kawasaki-shi (JP)

(21) Appl. No.: 16/155,917

(22) Filed: Oct. 10, 2018

(30) Foreign Application Priority Data
Oct. 13, 2017 (JP) 2017-199347

(51) Int. Cl. H05K 1/02; H05K 1/11; H05K 3/40

(52) U.S. Cl. CPC H05K 1/0251; H05K 2201/10409; H05K 3/4046; H05K 1/115

(57) ABSTRACT

A wiring board includes, a multilayer substrate including a plurality of wiring layers, a plurality of insulating layers, a via hole extending through a subset of the plurality of wiring layers and the plurality of insulating layers, and a screw via embedded in the via hole. The screw via includes a tip portion coupled to first wiring provided in any of the plurality of wiring layers, a core wire having a first end coupled to the tip portion, a head portion coupled to a second end of the core wire and coupled to second wiring located at a surface of the multilayer substrate, and a shank portion formed of an insulator at least on a surface thereof, covering a side surface of the core wire, and having a screw thread on the surface thereof. The tip portion, the core wire and the head portion are formed of a conductor.

### CROSS-REFERENCE TO RELATED APPLICATION

This application is based upon and claims the benefit of priority of the prior Japanese Patent Application No. 2017-199347, filed on Oct. 13, 2017, the entire contents of which are incorporated herein by reference.

### FIELD

The embodiments discussed herein are related to a wiring board and a manufacturing method for a wiring board.

### BACKGROUND

The following techniques are known techniques related to a wiring board including a via that couples wiring in one wiring layer to wiring in another wiring layer.

For example, there is known a method of manufacturing a wiring board, including forming a non-penetrating hole in a board including a plurality of wiring layers, disposing a conductive material on a bottom portion of the non-penetrating hole, inserting a thin conductive wire into the non-penetrating hole and joining the thin conductive wire with the conductive material, and filling the gap between the thin conductive wire and the side wall surface of the non-penetrating hole with an insulating material.

There is also known a technique for achieving impedance matching of a board by inserting, into a hole in a multilayered board, a component including a dielectric layer encasing a conductive ground core and a signal conductive layer coupled lateral to the dielectric layer.

There is also known a printed board structure including a via through-hole portion having a center conductor that connects a front-surface pattern and a back-surface pattern of a multilayered printed board, a covering conductor disposed around the center conductor, and an insulating material disposed between the center conductor and the covering conductor.

Related arts are disclosed in Japanese Laid-open Patent Publication Nos. 2015-128100 and 2006-191018, and Japanese Unexamined Utility Model Registration Application Publication No. 4-97380.

### SUMMARY

According to an aspect of the embodiments, a wiring board includes, a multilayer substrate including a plurality of wiring layers, a plurality of insulating layers, a via hole extending through a subset of the plurality of wiring layers and the plurality of insulating layers, and a screw via embedded in the via hole. The screw via includes a tip portion coupled to first wiring provided in any of the plurality of wiring layers, a core wire having a first end coupled to the tip portion, a head portion coupled to a second end of the core wire and coupled to second wiring located at a surface of the multilayer substrate, and a shank portion formed of an insulator at least on a surface thereof, covering a side surface of the core wire, and having a screw thread on the surface thereof. The tip portion, the core wire and the head portion are formed of a conductor.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a top view of a screw via according to an embodiment of the disclosed technique;

FIG. 2 is a side view of the screw via according to the embodiment of the disclosed technique;

FIG. 3 is a sectional view taken along the line III-III in FIG. 1;

FIG. 4 is a sectional view taken along the line IV-IV in FIG. 2;

FIG. 5 is an enlarged view of a tip portion of the screw via according to the embodiment of the disclosed technique;

FIG. 6 is a sectional view illustrating an example configuration of a wiring board in which the screw via according to the embodiment of the disclosed technique is embedded;

FIG. 7A is a sectional view illustrating an example method of manufacturing the wiring board according to the embodiment of the disclosed technique;

FIG. 7B is a sectional view illustrating the example method of manufacturing the wiring board according to the embodiment of the disclosed technique;

FIG. 7C is an enlarged sectional view of signal wiring according to the embodiment of the disclosed technique;

FIG. 7D is a sectional view illustrating the example method of manufacturing the wiring board according to the embodiment of the disclosed technique;

FIG. 7E is an enlarged sectional view of the signal wiring to which the tip portion of the screw via according to the embodiment of the disclosed technique is coupled;

FIG. 8A is a sectional view illustrating an example method of manufacturing a wiring board according to a comparative example;

FIG. 8B is a sectional view illustrating the example method of manufacturing the wiring board according to the comparative example;

FIG. 9 is a diagram illustrating a signal transmission path analyzed using simulation;

FIG. 10A is an eye diagram for a wiring board with 0.5-mm stubs;

FIG. 10B is an eye diagram for a wiring board without stubs;

FIG. 11 is a diagram illustrating the dimensions of the portions of the screw via according to the embodiment of the disclosed technique; and

FIG. 12 is a side view of a screw via according to another embodiment of the disclosed technique.

### DESCRIPTION OF EMBODIMENTS

In a wiring board including a plurality of wiring layers, the wiring layers are coupled using vias.

Part of a via may form a branch of wiring called a stub, and this stub may adversely affect a signal passing through signal wiring. For example, after reaching a point of branch into the stub and the signal wiring, a signal passing through the signal wiring splits into two, with one of them going to the stub, getting reflected by an end portion of the stub, and returning to the branch point. Then, the signal passing through the signal wiring and the signal reflected by the end portion of the stub interfere with each other, causing possible signal attenuation at the branch point.

A known approach to removing a stub is back-drilling. In back-drilling, a drill is inserted from the back surface of a wiring board at the position where a via is formed, thereby cutting and removing the stub. However, with back-drilling, it is difficult to remove a stub completely without cutting the signal wiring, and a stub of approximately 0.5 mm remains. A signal loss by reflection caused by a stub increases as the transmission rate of the signal increases, and even if back-drilling is employed, it is difficult to achieve high transmission of, for example, more than 25 gigabits per second (Gbps). While there are via techniques that do not produce stubs, such as skip vias or stack vias, they only allow fabrication of short vias extending for three wiring layers due to manufacturing limitation.

The following describes embodiments of the disclosed technique as examples with reference to the drawings. Throughout the drawings, the same or equivalent components are denoted by the same reference numerals.

### First Embodiment

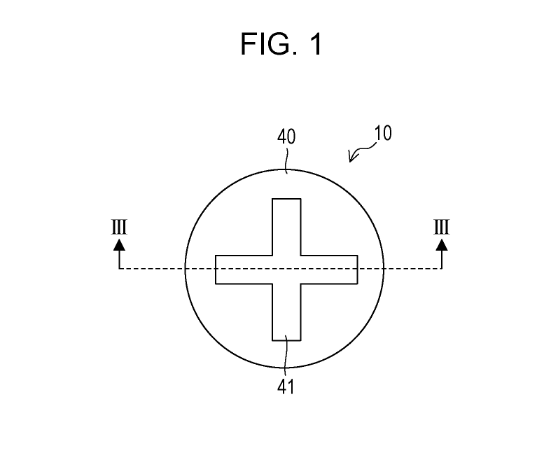

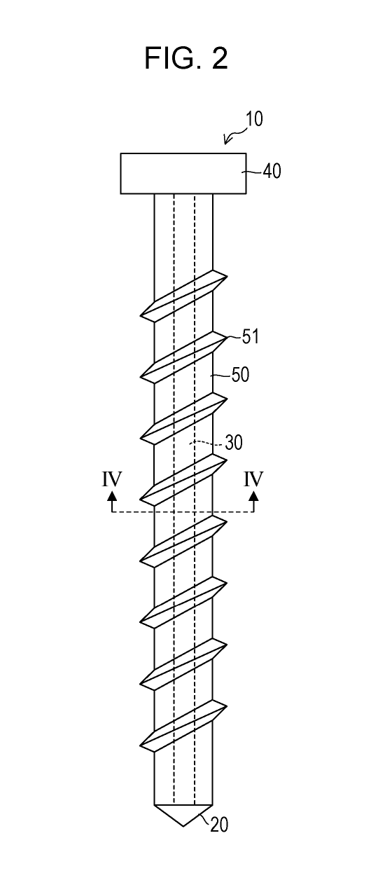

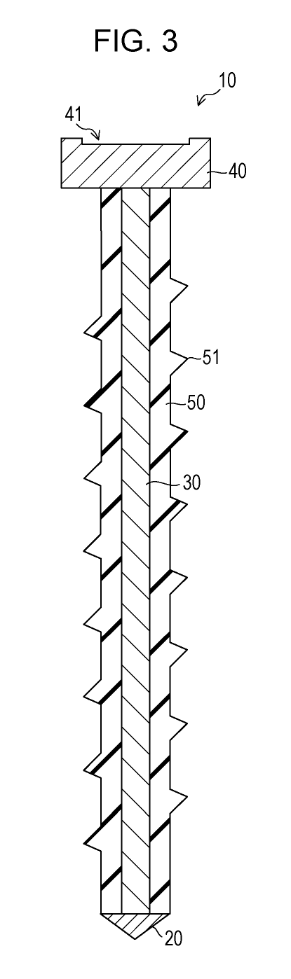

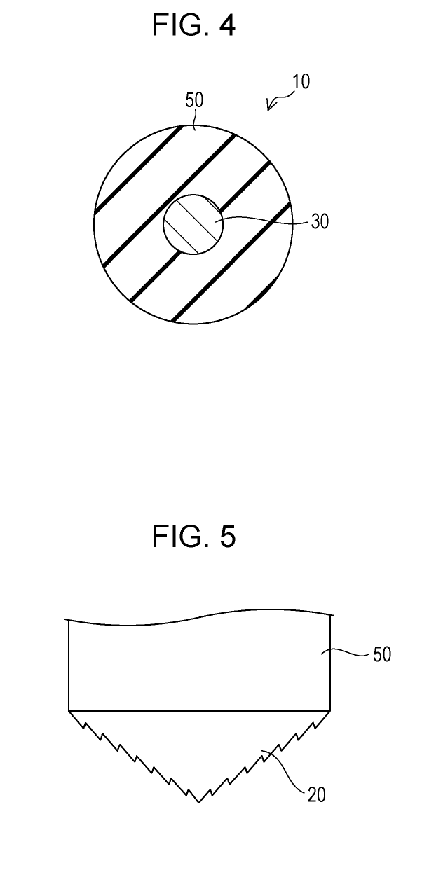

FIG. 1 is a top view of a screw via 10 according to an embodiment of the disclosed technique, FIG. 2 is a side view of the screw via 10, FIG. 3 is a sectional view taken along the line III-III in FIG. 1, and FIG. 4 is a sectional view taken along the line Iv-Iv in FIG. 2. The screw via 10 includes a tip portion 20, a core wire 30, a head portion 40, and a shank portion 50.

The tip portion 20 is formed of a conductor such as copper, and is disposed at the tip of the screw via 10. FIG. 5 is an enlarged view of the tip portion 20. As illustrated in FIG. 5, the tip portion 20 is treated with surface roughening treatment and has fine asperities formed on the surface. The tip portion 20 may be roughened by, for example, wet etching using an organic acid micro-etching agent.

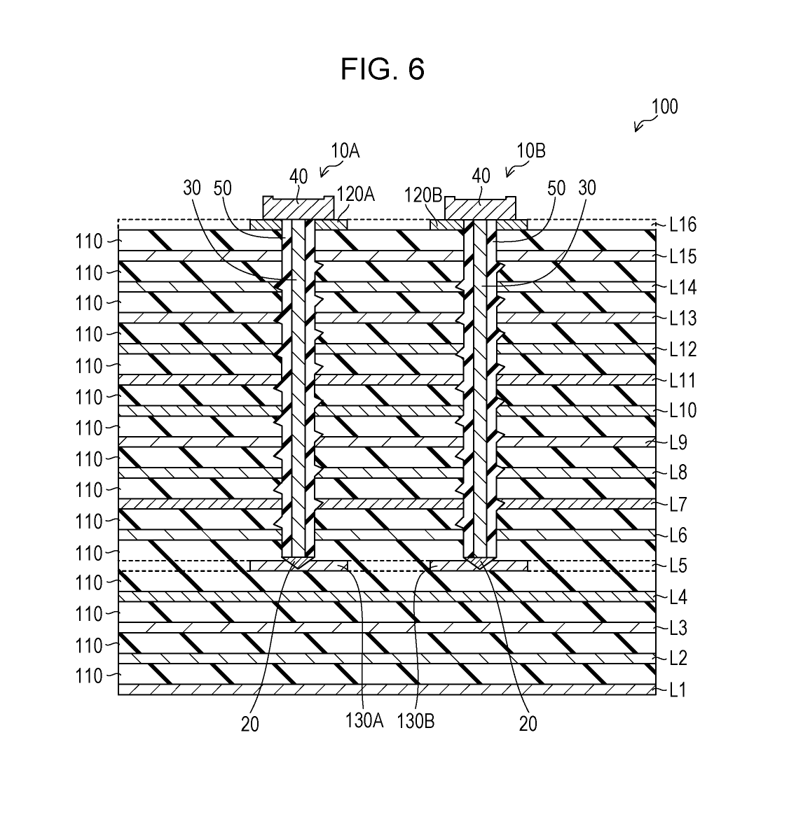

The core wire 30 is formed of a conductor such as copper, and has one end coupled to the tip portion 20. The head portion 40 is formed of a conductor such as copper, and is coupled to the other end of the core wire 30. For example, the head portion 40 is electrically coupled to the tip portion 20 through the core wire 30. As illustrated in FIG. 1, the head portion 40 has a cross-shaped groove 41 formed in the upper surface thereof. The groove 41 is used so that a tool such as a driver may abut the head portion 40, the tool being used to embed the screw via 10 into a wiring board 100 (see FIG. 6) to be described later.

The shank portion 50 covers the side surface of the core wire 30. For example, the core wire 30 is embedded inside the shank portion 50. The shank portion 50 has a screw thread 51 formed on the surface thereof. The shank portion 50 is insulated at least on the surface thereof, and preferably, is as hard as ceramics and is nonmagnetic. For example, Nasseel Insulation Skin (Nasseel IS) may be favorably used as a material for the shank portion 50. Nasseel IS is a member insulated by formation of a ceramic layer on the surface of a stainless-steel part. A resin material such as an epoxy resin may also be used as a material for the shank portion 50 as long as the resin material is as hard as ceramics.

FIG. 6 is a sectional view illustrating an example configuration of the wiring board 100 according to the embodiment of the disclosed technique, the wiring board 100 having screw vias 10A and 10B embedded therein. The screw vias 10A and 10B have the same configuration as the screw via 10 illustrated in FIGS. 1 to 5.

The wiring board 100 includes a plurality of wiring layers L1 to L16 stacked in the thickness direction of the wiring board 100 and a plurality of insulating layers 110 provided between the wiring layers. For example, the wiring layers and the insulating layers 110 are stacked alternately. The number of wiring layers provided in the wiring board 100 may be increased or decreased appropriately. In the present embodiment, the wiring layers L1, L3, L5, L7, L10, L12, L14, and L16 are wiring layers in each of which signal wiring is formed, and the wiring layers L2, L4, L6, L8, L9, L11, L13, and L15 are wiring layers in each of which a ground plane is formed. The wiring layers L1 and L16 are wiring layers disposed at the outermost surfaces of the wiring board 100.

The screw vias 10A and 10B penetrate from the surface of the wiring board 100 through the wiring layers L16 to L6 and the insulating layers 110 provided between the wiring layers L16 to L6, and reach the wiring layer L5. The screw via 10A has the tip portion 20 coupled to signal wiring 130A provided in the wiring layer L5, and the head portion 40 coupled to signal wiring 120A provided in the wiring layer L16. For example, the signal wiring 120A and the signal wiring 130A are electrically coupled through the screw via 10A. Similarly, the screw via 10B has the tip portion 20 coupled to signal wiring 130B provided in the wiring layer L5, and the head portion 40 coupled to signal wiring 120B provided in the wiring layer L16. For example, the signal wiring 120B and the signal wiring 130B are electrically coupled through the screw via 10B. The signal wiring 120A and 130A may be signal wiring through which one of paired differential signals passes, and the signal wiring 120B and 130B may be signal wiring through which the other one of the paired differential signals passes.

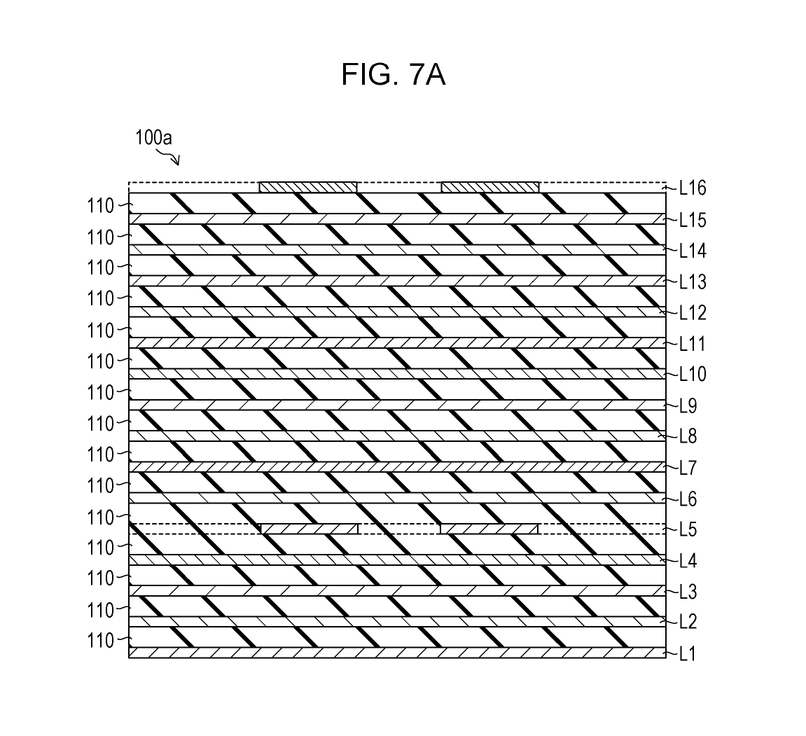

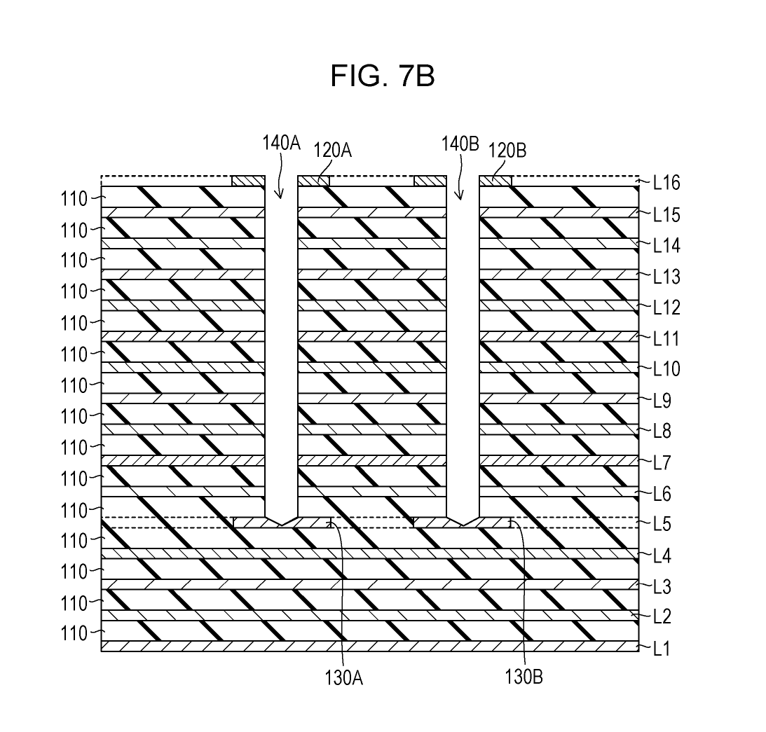

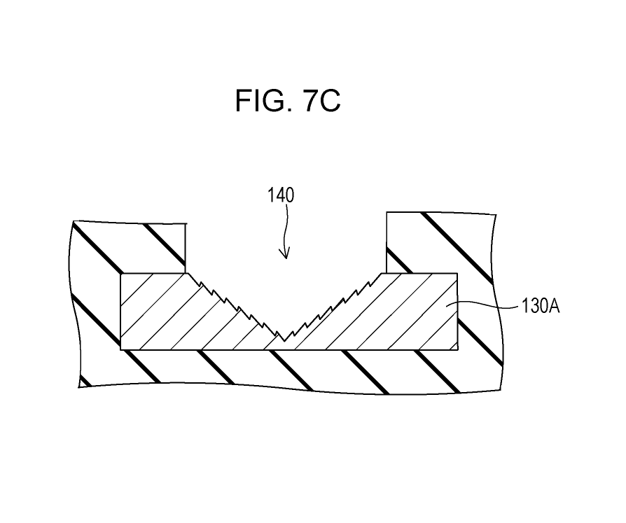

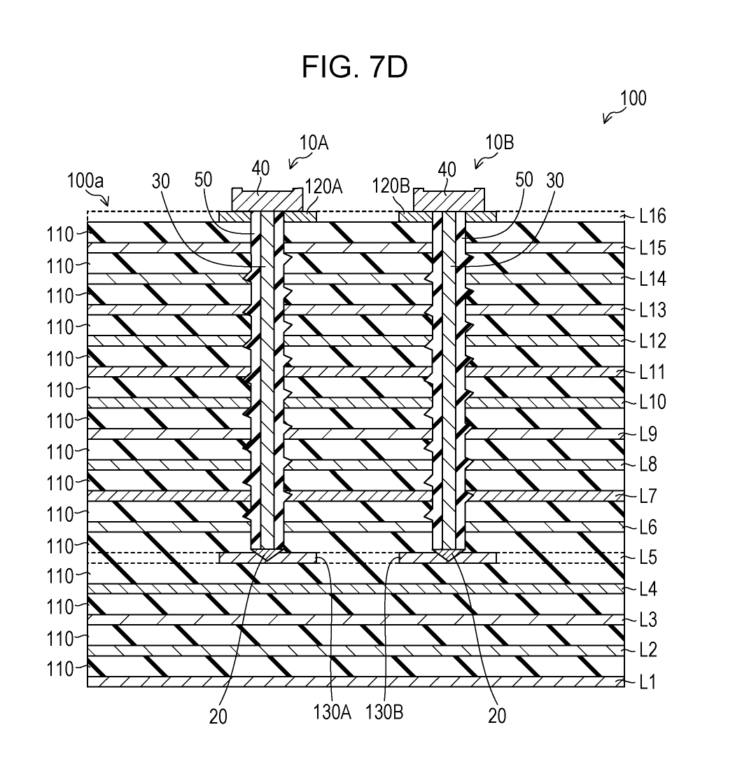

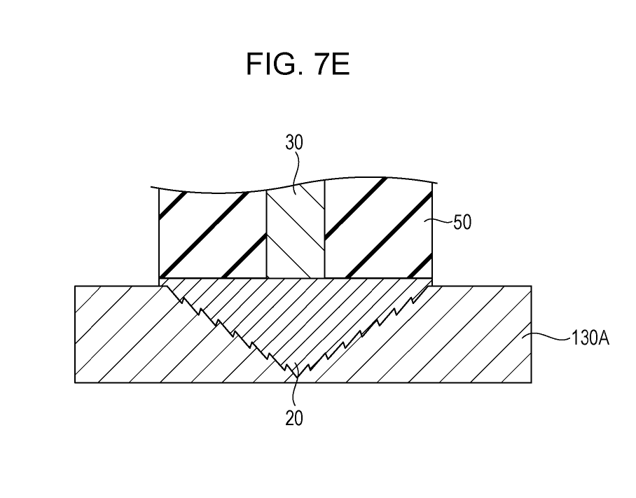

The following describes a method of manufacturing the wiring board 100 with reference to FIGS. 7A to 7E. First, a board 100a having the wiring layers L1 to L16 stacked between the insulating layers 110 is prepared (FIG. 7A). The board 100a may be fabricated using a known method.

Next, by drilling, via holes 140A and 140B are formed at positions on the board 100a where the screw vias 10A and 10B are to be formed (FIG. 7B). The via holes 140A and 140B are formed from the surface of the board 100a, penetrate through the wiring layers L16 to L6, and reach the signal wiring 130A and 130B provided in the wiring layer L5, respectively. In this step, the drill is positioned so that the tip of the drill may come into contact with the signal wiring 130A and 130B with the drill not penetrating through the signal wiring 130A and 130B. The insertion depth of the drill may be designated in units of micrometers (μm).

Preferably, the via holes 140A and 140B are formed using a drill having a roughened tip. FIG. 7C is an enlarged sectional view of the signal wiring 130A in which a via hole 140A is formed using a drill with a roughened tip. When the surface of the signal wiring 130A is cut by a drill with a roughened tip in the formation of the via hole 140A, asperities are formed on the surface of the signal wiring 130A. The same is true with the signal wiring 130B.

Next, the screw vias 10A and 10B are inserted into the via holes 140A and 140B, respectively (FIG. 7D). In this step, a tool such as a driver may be used to insert the screw vias 10A and 10B by axially rotating them. In this case, the tip of the driver is fitted into the groove 41 formed in the upper surface of the head portion 40 of each of the screw vias 10A and 10B. As to the screw via 10A, the tip portion 20 is coupled to the signal wiring 130A formed in the wiring layer L5, and the head portion 40 is coupled to the signal wiring 120A formed in the wiring layer L16 at the surface of the board 100a. Thereby, the signal wiring 120A and the signal wiring 130A are electrically coupled to each other through the head portion 40, the core wire 30, and the tip portion 20 of the screw via 10A. Similarly, as to the screw via 10B, the tip portion 20 is coupled to the signal wiring 130B formed in the wiring layer L5, and the head portion 40 is coupled to the signal wiring 120B formed in the wiring layer L16 at the surface of the board 100a. Thereby, the signal wiring 120B and the signal wiring 130B are electrically coupled to each other through the head portion 40, the core wire 30, and the tip portion 20 of the screw via 10B.

FIG. 7E is an enlarged sectional view of the signal wiring 130A to which the tip portion 20 of the screw via 10A is coupled. When asperities are formed on the surface of the signal wiring 130A in the step of forming the via hole 140A, and the tip portion 20 of the screw via 10A is treated with surface roughening treatment, the area of contact between the tip portion 20 and the signal wiring 130A may be increased. This allows reduction in the risk of contact failure occurring between the screw via 10A and the signal wiring 130A, and also, reduction in the contact resistance between the screw via 10A and the signal wiring 130A. The same is true with the screw via 10B and the signal wiring 130B.

Through the above steps, the wiring board 100 is completed. In a later reflow step of soldering a component to the wiring board 100, the tip portions 20 of the screw vias 10A and 10B and the conductors forming the signal wiring 130A and 130B soften, strengthening the joint between the conductors. When the tip portions 20 and the signal wiring 130A and 130B have roughened surfaces, anchor effect is produced, making it possible to enhance the joint strength between the screw via 10A and the signal wiring 130A and the joint strength between the screw via 10B and the signal wiring 130B.

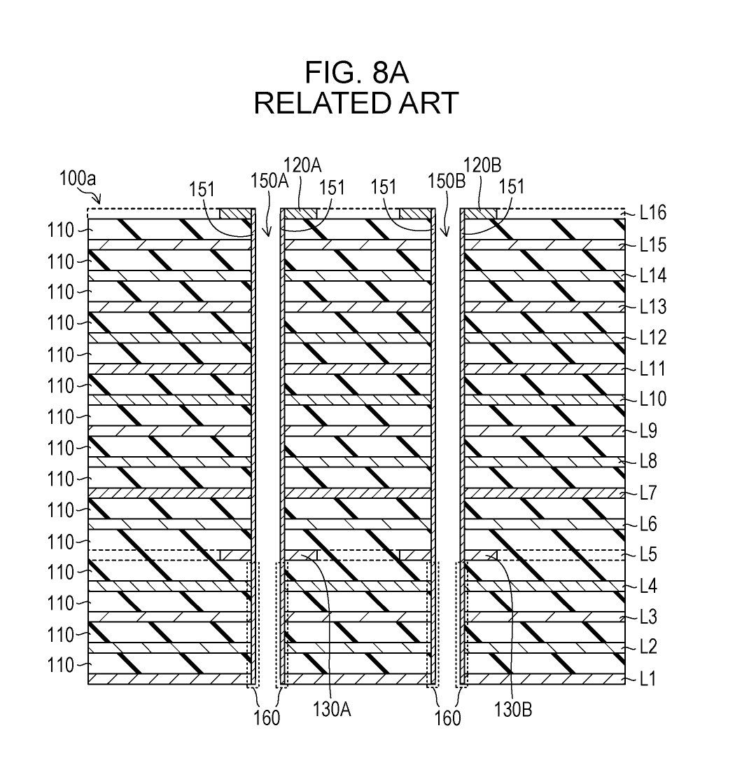

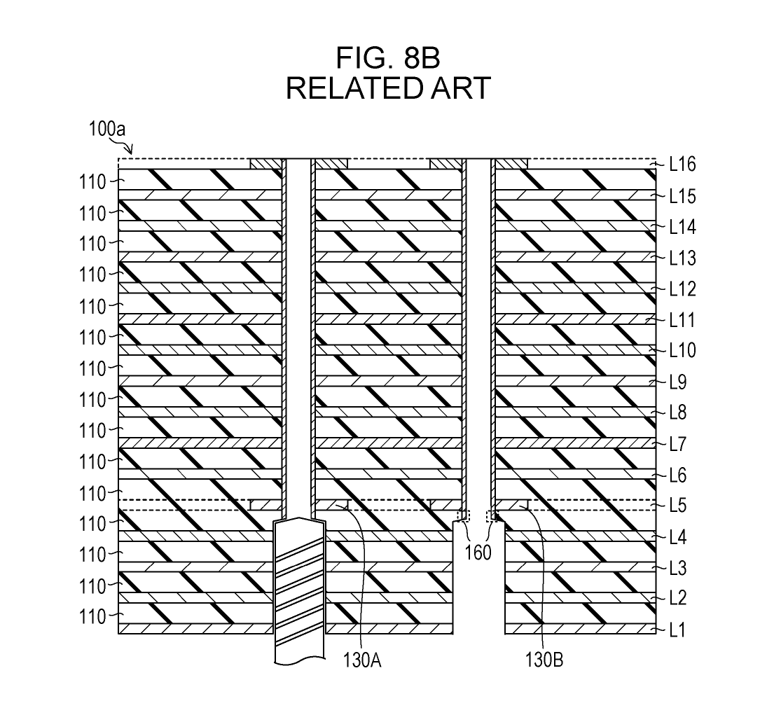

FIGS. 8A and 8B are sectional views illustrating an example method of manufacturing a wiring board according to a comparative example. In the manufacturing method according to the comparative example, as illustrated in FIG. 8A, through-holes 150A and 150B penetrating the board 100a are formed, and by plating, a conductive film 151 is formed on the inner walls of the through-holes 150A and 150B. Thereby, through the conductive film 151, the signal wiring 130A and 130B provided in the wiring layer L5 are electrically coupled respectively to the signal wiring 120A and 120B provided in the wiring layer L16. Stubs 160 are formed by parts of the conductive film 151 formed on the inner walls of the through-holes 150A and 150B, the parts being extending from the wiring layer L5 to the wiring layer L1.

Next, as illustrated in FIG. 8B, using publicly-known back-drilling, the stubs 160 are removed using a drill from the back-surface side of the board 100a. However, with back-drilling, it is difficult to remove the stubs 160 completely without cutting the signal wiring 130A and 130B, and the stubs 160 of approximately 0.5 mm remain. Generally, a signal loss by reflection caused by stubs increases as the transmission rate of the signal increases, and even the stubs of approximately 0.5 mm adversely affect the signal transmission quality in high-speed transmission exceeding 25 Gbps.

On the other hand, in the wiring board 100 according to the disclosed technique, no stub is generated since interlayer connection of wiring provided in the wiring layers L1 to L16 is achieved by embedment of the screw vias 10A and 10B into the board 100a. Thus, deterioration in signal transmission quality due to stubs is reduced.

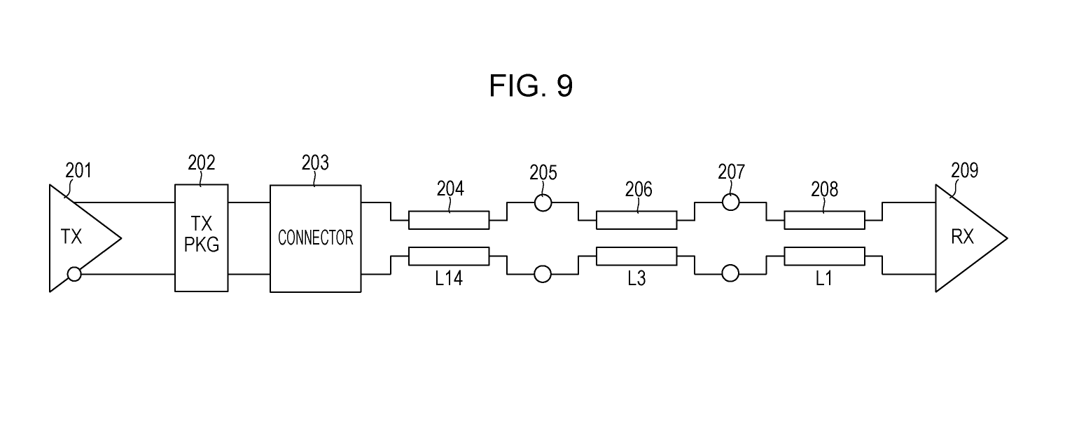

Through simulation, a comparison of signal transmission quality was made using eye diagrams between a wiring board with 0.5-mm stubs and a wiring board without stubs. FIG. 9 is a diagram illustrating a signal transmission path analyzed using simulation (analysis topology). In this analysis, as illustrated in FIG. 9, it was assumed that a differential signal was transmitted from a transmitter (TX) 201 to a receiver (RX) 209 through a TX package 202, a connector 203, and signal wiring 204, 206, and 208 and vias 205 and 207 of the wiring board. It was also assumed here that inside the wiring board, the differential signal passed through the signal wiring 204 (5 mm) in the wiring layer L14, the via 205 connecting the wiring layers L14 and L3, the signal wiring 206 (50 mm) in the wiring layer L3, the via 207 connecting the wiring layers L3 and L1, and the signal wiring 208 (70 mm) in the wiring layer L1. The transmission rate of the differential signal was 28.05 Gbps. As a differential signal pattern, a pseudo random pattern (PRBS15 (100000 bits)) was used. For the transmitter (Tx) 201, the deterministic jitter Dj was 1.78 ps, and the random jitter Rj was 0.25 ps.

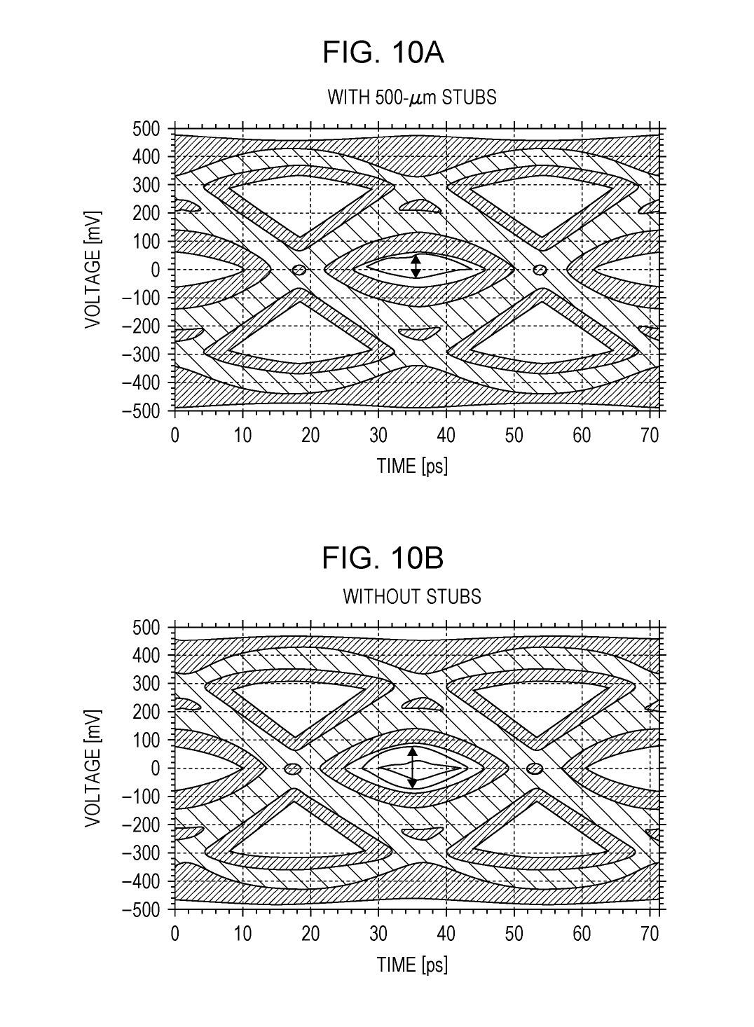

FIG. 10A is an eye diagram for the wiring board with 0.5-mm stubs. FIG. 10B is an eye diagram for the wiring board without stubs. An eye diagram is obtained by sampling waveforms of transmitted signals and superimposing them. Transmission quality is determined in such a way that transmission quality is higher when the eye height in the voltage axis direction and the eye width in the time axis direction of the eye pattern that appears in the center of the waveforms are both larger. In the wiring board with 0.5-mm stubs illustrated in FIG. 10A, the eye height of the eye pattern in the voltage axis direction was 90 mV. On the other hand, in the wiring board without stubs illustrated in FIG. 10B, the eye height of the eye pattern in the voltage axis direction was 135 mV. For example, complete removal of stubs increased the eye height of the eye pattern in the voltage axis direction by 45 mV and improved the signal transmission quality. Having no stubs, the wiring board 100 according to the embodiment of the disclosed technique supposedly achieves results similar to those illustrated in FIG. 10B.

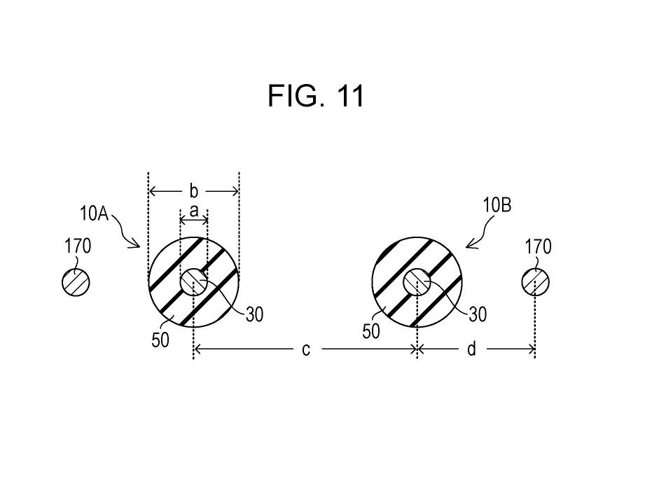

In the wiring board 100 according to the embodiment of the disclosed technique, the impedance of the screw vias 10A and 10B is controllable by changing of the relative permittivity and diameter of the shank portion 50, the diameter of the core wire 30, and the like of the screw vias 10A and 10B. Impedance of the screw vias 10A and 10B was calculated with changes made to the values of the diameter a of the core wire 30, the diameter b of the shank portion 50, the interval c between the core wires 30, and the distance d between each core wire 30 and the closest ground via 170, as illustrated in FIG. 11. Table 1 below depicts the results. The relative permittivity of the shank portion 50 was 3.8 in each level. By changing the values of a to d as depicted in Table 1, the impedance of the screw vias 10A and 10B changed within a range from 68.1 Ω to 91.1 Ω.

TABLE 1

| | a | b | c | d | Impedance |
|---|---|---|---|---|---|
| Level | [μm] | [μm] | [μm] | [μm] | [Ω] |
| 1 | 50 | 250 | 600 | 500 | 68.1 |
| 2 | 50 | 250 | 700 | 500 | 71.2 |
| 3 | 50 | 250 | 800 | 500 | 73.4 |
| 4 | 50 | 250 | 800 | 800 | 76.5 |
| 5 | 50 | 250 | 800 | 1000 | 77.5 |
| 6 | 50 | 300 | 800 | 500 | 77.6 |
| 7 | 50 | 400 | 800 | 500 | 91.1 |

As the results demonstrate, in the wiring board 100 according to the embodiment of the disclosed technique, the impedance of the screw vias 10A and 10B is readily controllable. When there is impedance mismatch between the screw vias 10A and 10B and the signal wiring 120A, 130A, 120B, and 130B coupled to the screw vias 10A and 10B, signal transmission quality lowers due to reflection. Thus, at least one of the values of a to d is preferably adjusted in order to make small the difference between the impedance of the screw vias 10A and 10B and the impedance of the signal wiring 120A, 130A, 120B, and 130B coupled thereto. This allows reduction in signal reflection due to impedance mismatch and improvement in signal transmission quality.

In the wiring board 100 according to the present embodiment, the tip portions 20 of the screw vias 10A and 10B and the signal wiring 130A, 130B have roughened surfaces, so that the area of contact between the screw via 10A and the signal wiring 130A and between the screw via 10B and the signal wiring 130B are increased. This in turn achieves reduction in the contact resistance between the screw via 10A and the signal wiring 130A and between the screw via 10B and the signal wiring 130B. The anchor effect allows enhancement of the joint strength between the screw via 10A and the signal wiring 130A and between the screw via 10B and the signal wiring 130B.

Although the present embodiment describes an example where the screw vias 10A and 10B are used to connect the signal wiring 120A and 120B provided in the wiring layer L16 to the signal wiring 130A and 130B provided in the wiring layer L5, respectively, the disclosed technique is not limited to such a mode. The screw vias 10A and 10B may be used to connect wiring in any of the wiring layers provided inside the wiring board 100 to wiring in the wiring layer provided at the outermost surface of the wiring board.

Although the present embodiment describes an example where the screw vias 10A and 10B are disposed on transmission paths through which differential signals pass, screw vias may be disposed on transmission paths through which single-ended signals pass.

### Second Embodiment

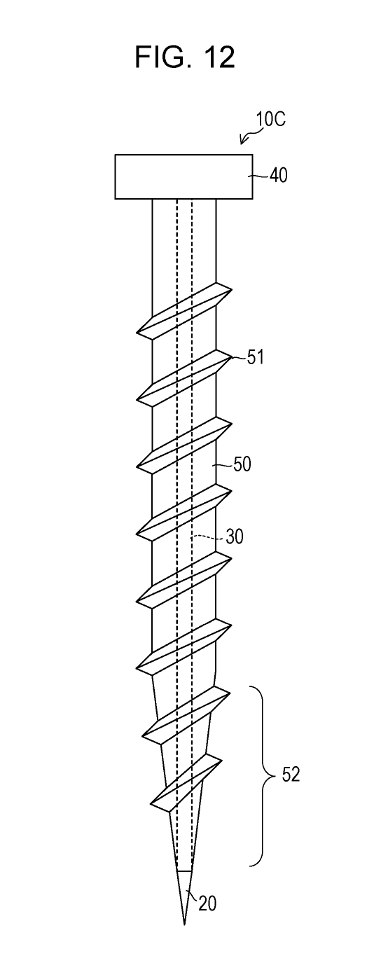

FIG. 12 is a side view of a screw via 10C according to a second embodiment of the disclosed technique. The shank portion 50 of the screw via 10C has a tapered portion 52 whose diameter becomes smaller and smaller from the head portion 40 side to the tip portion 20 side. For example, the screw via 10C is sharp near the tip portion 20 and is shaped like a wood screw. Being sharp near the tip portion 20, the screw via 10C according to the present embodiment is readily embedded into a board. The screw via 10C may be embedded into the board while functioning as a drill. Thus, a step of forming via holes in the board may be omitted.

The wiring board 100 is an example of a wiring board in the disclosed technique. The screw via 10, 10A, 10B, and 10C are an example of a screw via in the disclosed technique. The tip portion 20 is an example of a tip portion in the disclosed technique. The core wire 30 is an example of a core wire in the disclosed technique. The head portion 40 is an example of a head portion in the disclosed technique. The shank portion 50 is an example of a shank portion in the disclosed technique. The wiring layers L1 to L16 are examples of wiring layers in the disclosed technique. The signal wiring 130A and 130B are an example of first wiring in the disclosed technique. The signal wiring 120A and 120B are an example second wiring in the disclosed technique.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A wiring board comprising:
a multilayer substrate including a plurality of wiring layers, a plurality of insulating layers, and a via hole extending through a subset of the plurality of wiring layers and a subset of the plurality of insulating layers; and
a screw via embedded in the via hole, the screw via including
a tip portion formed of a conductor, the tip portion coupled to first wiring provided in any of the subset of the plurality of wiring layers,
a core wire formed of a conductor and having a first end coupled to the tip portion,
a head portion formed of a conductor, the head portion coupled to a second end of the core wire and coupled to second wiring provided in the subset of the plurality of wiring layers, the second wiring located at a surface of the multilayer substrate, and
a shank portion formed of an insulator at least on a surface thereof, covering a side surface of the core wire, and having a screw thread on the surface thereof.

2. The wiring board according to claim 1, wherein the tip portion has a roughened surface.

3. The wiring board according to claim 1, wherein a part of the first wiring that is coupled to the tip portion is roughened.

4. The wiring board according to claim 1, wherein the tip portion does not extend past the first wiring.

5. The wiring board according to claim 1, wherein a differential signal passes through at least one of the first wiring and the second wiring.

6. The wiring board according to claim 1, wherein the shank portion has a tapered portion whose diameter becomes smaller from the head portion side to the tip portion side.

7. A manufacturing method for a wiring board including a multilayer substrate, the method comprising:
forming a via hole on the multilayer substrate;
embedding, into the multilayer substrate at a position of the via hole, a screw via including a tip portion formed of a conductor, a core wire formed of a conductor and having a first end coupled to the tip portion, a head portion formed of a conductor and coupled to a second end of the core wire, and a shank portion formed of an insulator at least on a surface thereof, covering a side surface of the core wire, and having a screw thread on the surface thereof;
coupling the tip portion to first wiring provided inside the multilayer substrate; and
coupling the head portion to second wiring provided at a surface of the multilayer substrate.

8. The manufacturing method according to claim 7, wherein the via hole extends to the first wiring provided inside the multilayer substrate and does not extend past the first wiring.

9. The manufacturing method according to claim 7, wherein the tip portion has a roughened surface.

10. The manufacturing method according to claim 7, wherein a part of the first wiring that is coupled to the tip portion is roughened.

11. The manufacturing method according to claim 7, wherein the screw via is coupled to wiring through which a differential signal passes.
